(19) United States
(12) Patent Application Publication
(10) Pub. No.: US 2026/0088059 A1
(43) Pub. Date: Mar. 26, 2026

(54) SEMICONDUCTOR MEMORY DEVICE

(71) Applicant: SK hynix Inc., Icheon-si (KR)

(72) Inventors: Jae Hyeong HONG, Icheon-si (KR); Beom Kyu SEO, Icheon-si (KR); Keun Seon AHN, Icheon-si (KR); Soon Sung AN, Icheon-si (KR); Sung Hwa OK, Icheon-si (KR); Jung Yeop LEE, Icheon-si (KR); Ji Young LEE, Icheon-si (KR); Jun Seo JANG, Icheon-si (KR); Kyeong Min CHAE, Icheon-si (KR); Eun Ji CHOI, Icheon-si (KR)

(21) Appl. No.: 19/071,283

(22) Filed: Mar. 5, 2025

(30) Foreign Application Priority Data
Sep. 25, 2024 (KR) 10-2024-0129688

(51) Int. Cl. G11C 5/06

(52) U.S. Cl. CPC G11C 5/063

(57) ABSTRACT

A semiconductor memory device includes: a pair of first power supply voltage pads; a second power supply voltage pad; a first data input/output pad connected to a first data output driver; and a second data input/output pad connected to a second data output driver. The first data output driver is connected to one of the pair of first power supply voltage pads, and the second data output driver is connected to the other of the pair of first power supply voltage pads. The first data input/output pad is disposed between one of the pair of first power supply voltage pads and the second power supply voltage pad, and the second data input/output pad is disposed between the other of the pair of first power supply voltage pads and the second power supply voltage pad.

### CROSS-REFERENCE TO RELATED APPLICATION

The present application claims priority under 35 U.S.C. § 119(a) to Korean Patent Application No. 10-2024-0129688 filed in the Korean Intellectual Property Office on Sep. 25, 2024, which is incorporated herein by reference in its entirety.

### BACKGROUND

### 1. Technical Field

Embodiments of the present disclosure generally relate to a semiconductor memory device.

### 2. Related Art

A semiconductor memory device receives write data from a memory controller and transmits read data to the memory controller.

In a synchronous semiconductor memory device, both a memory controller and a semiconductor memory device operate in synchronization with a system clock. When data is transmitted between the memory controller and the semiconductor memory device, a skew may occur between the data and the system clock because the loading and traces of the data and the system clock are different and because of location differences between the system clock and the semiconductor memory device.

In order to reduce skew, when transmitting data between the memory controller and the semiconductor memory device, a data strobe signal is transmitted together with the data. Because the data strobe signal has the same loading and trace as the data, skew may be minimized by strobing data using a data strobe signal in a semiconductor memory device.

A timing parameter, tDQSQ, represents time characteristics prescribed by JEDEC (Joint Electron Device Engineering Council) and is associated with skew between a read data strobe signal and read data. A reduction in tDQSQ deviation between read data can stabilize characteristics of read data.

### SUMMARY

Various embodiments of the present disclosure are directed to providing a semiconductor memory device capable of reducing tDQSQ deviation and tDVW (data valid window) deviation between read data through even distribution of power and reference voltage generation circuits (DAC) and by reducing settling time deviation of reference voltages for read data.

In an embodiment, a semiconductor memory device may include: a pair of first power supply voltage pads; a second power supply voltage pad; a first data input/output pad connected to a first data output driver; and a second data input/output pad connected to a second data output driver, wherein the first data output driver is connected to one of the pair of first power supply voltage pads, and the second data output driver is connected to the other of the pair of first power supply voltage pads, and wherein the first data input/output pad is disposed between one of the pair of first power supply voltage pads and the second power supply voltage pad, and the second data input/output pad is disposed between the other of the pair of first power supply voltage pads and the second power supply voltage pad.

In an embodiment, a semiconductor memory device may include: a plurality of first power supply voltage pads; a plurality of second power supply voltage pads; and plurality of data input/output pads connected to a plurality of data output drivers, respectively, wherein, from among the plurality of first power supply voltage pads and from among the plurality of second power supply voltage pads, a first power supply voltage pad is disposed between a pair of adjacent second power supply voltage pads, wherein, from among the plurality of first data input/output pads, a first data input/output pad is disposed between one of the pair of second power supply voltage pads and the first power supply voltage pad, and a second data input/output pad is disposed between the other of the pair of second power supply voltage pads and the first power supply voltage pad, and wherein a data output driver connected to the first data input/output pad and a data output driver connected to the second data input/output pad are connected in common to the first power supply voltage pad.

In an embodiment, a semiconductor memory device may include: first and second data input/output pads defined in a pad layer on a substrate; a first data input circuit defined in the substrate and connected to the first data input/output pad; a second data input circuit defined in the substrate and connected to the second data input/output pad; a first reference voltage generation circuit defined in the substrate, and providing a reference voltage to the first data input circuit; a second reference voltage generation circuit defined in the substrate, and providing a reference voltage to the second data input circuit; and a first power supply voltage pad defined in the pad layer, and disposed between the first data input/output pad and the second data input/output pad, wherein, when viewed in a plan view, the first and second reference voltage generation circuits are disposed between the first data input/output pad and the second data input/output pad.

According to embodiments of the present disclosure, it is possible to provide a semiconductor memory device capable of reducing tDQSQ deviation and tDVW (data valid window) deviation between read data through even distribution of power.

According to embodiments of the present disclosure, it is possible to provide a semiconductor memory device capable of shortening the settling time of a reference voltage and reducing a settling time deviation between reference voltages for read data through even distribution of reference voltage generation circuits (DAC).

### BRIEF DESCRIPTION OF THE DRAWINGS

FIG. 1 is a schematic plan view of a semiconductor memory device according to an embodiment of the present disclosure.

FIG. 2 is a block diagram of a data output driver according to an embodiment of the present disclosure.

FIG. 3 is a schematic plan view of a semiconductor memory device according to an embodiment of the present disclosure.

FIG. 4 is a perspective view illustrating pads and reference voltage generation circuits of a semiconductor memory device according to an embodiment of the present disclosure.

FIG. 5 is a schematic plan view of a semiconductor memory device according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through one or more intervening elements. When two elements are identified as “directly connected” or “directly coupled,” one element is directly connected or directly coupled to the other element without any intervening element.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise to limit scope. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

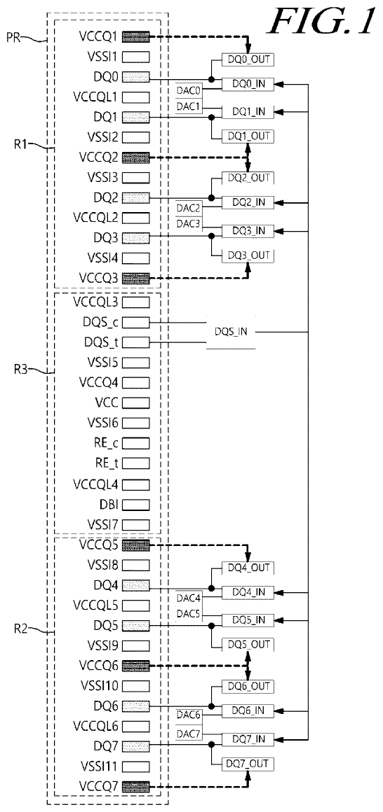

FIG. 1 is a schematic plan view of a semiconductor memory device according to an embodiment of the present disclosure.

Referring to FIG. 1, a semiconductor memory device includes first to eighth data input/output pads DQ0 to DQ7, a plurality of first power supply voltage pads VCCQ1 to VCCQ7, a plurality of second power supply voltage pads VCCQL1 to VCCQL6, first to eighth data output drivers DQ0_OUT to DQ7_OUT, first to eighth data input circuits DQ0_IN to DQ7_IN, and first to eighth reference voltage generation circuits DAC0 to DAC7. The semiconductor memory device according to embodiment may further includes a plurality of ground pads VSSI1 to VSSI11, data strobe pads DQS_t and DQS_c, read enable pads RE_t and RE_c, a data mask pad DBI, a third power supply voltage pad VCC, and a data strobe signal input circuit DQS_IN.

The semiconductor memory device has a pad region PR. In an embodiment, the pad region PR may be located on one side of an edge region of a semiconductor memory device.

The pad region PR may include first to third regions R1 to R3. The first to third regions R1 to R3 may be disposed in a line. The first region R1 and the second region R2 may be spaced apart from each other, and the third region R3 may be disposed between the first region R1 and the second region R2.

The first to eighth data input/output pads DQ0 to DQ7 may be grouped into two groups which are disposed in the first region R1 and the second region R2, respectively. Specifically, the first to fourth data input/output pads DQ0 to DQ3 may be grouped into a first group and be disposed in the first region R1, and the fifth to eighth input/output pads DQ4 to DQ7 may be grouped into a second group and be disposed in the second region R2.

In the first region R1, four data input/output pads DQ0 to DQ3, three first power supply voltage pads VCCQ1 to VCCQ3, two second power supply voltage pads VCCQL1 and VCCQL2 and four ground pads VSSI1 to VSSI4 may be disposed.

In the first region R1, two data input/output pads may be disposed between two adjacent first power supply voltage pads. One second power supply voltage pad may be disposed between two data input/output pads, which are disposed between two adjacent first power supply voltage pads. For example, the first and second data input/output pads DQ0 and DQ1 are disposed between the first power supply voltage pad VCCQ1 and the first power supply voltage pad VCCQ2, and the second power supply voltage pad VCCQL1 is disposed between the first data input/output pad DQ0 and the second data input/output pad DQ1. The third and fourth data input/output pads DQ2 and DQ3 are disposed between the first power supply voltage pad VCCQ2 and the first power supply voltage pad VCCQ3, and the second power supply voltage pad VCCQL2 is disposed between the third data input/output pad DQ2 and the fourth data input/output pad DQ3.

In the first region R1, a ground pad is disposed between a data input/output pad and a first power supply voltage pad. For example, in FIG. 1 the ground pad VSSI1 is disposed between the first data input/output pad DQ0 and the first power supply voltage pad VCCQ1, the ground pad VSSI2 is disposed between the second data input/output pad DQ1 and the first power supply voltage pad VCCQ2, the ground pad VSSI3 is disposed between the third data input/output pad DQ2 and the first power supply voltage pad VCCQ2, and the ground pad VSSI4 is disposed between the fourth data input/output pad DQ3 and the first power supply voltage pad VCCQ3.

The spacing between the first data input/output pad DQ0 and the first power supply voltage pad VCCQ1, the spacing between the second data input/output pad DQ1 and the first power supply voltage pad VCCQ2, the spacing between the third data input/output pad DQ2 and the first power supply voltage pad VCCQ2 and the spacing between the fourth data input/output pad DQ3 and the first power supply voltage pad VCCQ3 may be the same.

In the second region R2, four data input/pad DQ4 to DQ7, three first power supply voltage pads VCCQ5 to VCCQ7, two second power supply voltage pads VCCQL5 and VCCQL6 and four ground pads VSSI8 to VSSI11 may be disposed. The arrangement of these elements and the pad disposition structure of the second region R2 is similar to that of the first region R1, and thus, repeated descriptions will be omitted.

In the third region R3, the data strobe pads DQS_t and DQS_c, the read enable pads RE_t and RE_c, one first power supply voltage pad VCCQ4, two second power supply voltage pads VCCQL3 and VCCQL4 and three ground pads VSSI5 to VSSI7 may be disposed.

The first to eighth data input/output pads DQ0 to DQ7 may be used to receive data, commands and addresses from a memory controller. The first to eighth data input/output pads DQ0 to DQ7 may be used to output data to the memory controller. FIG. 1 includes, for example, eight data input/output pads DQ0 to DQ7, but other embodiments are not limited thereto. The number of data input/output pads may vary depending on the type of semiconductor memory device.

The first to eighth data output drivers DQ0_OUT to DQ7_OUT may be connected to the first to eighth data input/output pads DQ0 to DQ7, respectively. The first to eighth data output drivers DQ0_OUT to DQ7_OUT may output data read from a memory region (not illustrated) inside a semiconductor memory device to the first to eighth data input/output pads DQ0 to DQ7 in response to a data strobe signal, and accordingly, read data may be transmitted to the memory controller.

Each of the first to eighth data output drivers DQ0_OUT to DQ7_OUT may be disposed adjacent to a corresponding data input/output pad. For example, the first data output driver DQ0_OUT may be disposed adjacent to the first data input/output pad DQ0, and the second data output driver DQ1_OUT may be disposed adjacent to the second data input/output pad DQ1.

Because a data output driver is disposed adjacent to a corresponding data input/output pad, the length of a signal line that connects the data output driver and the data input/output pad may be minimized, and time delay that occurs between output of read data from the data output driver and transmission of the read data to the data input/output pad may be reduced.

The first data output driver DQ0_OUT may be connected to the first power supply voltage pad VCCQ1 through a power line, and may be supplied with a first power supply voltage from the first power supply voltage pad VCCQ1. The second data output driver DQ1_OUT and the third data output driver DQ2_OUT may be connected in common to the first power supply voltage pad VCCQ2 through a power line, and may be supplied with a first power supply voltage from the first power supply voltage pad VCCQ2. The fourth data output driver DQ3_OUT may be connected to the first power supply voltage pad VCCQ3 through a power line, and may be supplied with a first power supply voltage from the first power supply voltage pad VCCQ3.

The fifth data output driver DQ4_OUT may be connected to the first power supply voltage pad VCCQ5 through a power line, and may be supplied with a first power supply voltage from the first power supply voltage pad VCCQ5. The sixth data output driver DQ5_OUT and the seventh data output driver DQ6_OUT may be connected in common to the first power supply voltage pad VCCQ6 through a power line, and may be supplied with a first power supply voltage from the first power supply voltage pad VCCQ6. The eighth data output driver DQ7_OUT may be connected to the first power supply voltage pad VCCQ7 through a power line, and may be supplied with a first power supply voltage from the first power supply voltage pad VCCQ7.

A data input/output pad and a first power supply voltage pad are connected to in common one of the first to eighth data output drivers DQ0_OUT to DQ7_OUT. The spacing between a data input/output pad and a first power supply voltage pad that are connected to in common one of the first to eighth data output drivers DQ0_OUT to DQ7_OUT may be substantially similar to the spacing between a data input/output pad and a first power supply voltage pad that are connected to in common the other of the first to eighth data output drivers DQ0_OUT to DQ7_OUT. For example, the spacing between the first data input/output pad DQ0 and the first power supply voltage pad VCCQ1 that are connected to in common the first data output driver DQ0_OUT may be the same as the spacing between the second data input/output pad DQ1 and the first power supply voltage pad VCCQ2 that are connected to in common the second data output driver DQ1_OUT.

As a result, the distances from the respective first to eighth data output drivers DQ0_OUT to DQ7_OUT to corresponding first power supply voltage pads VCCQ1 to VCCQ3 and VCCQ5 to VCCQ6 may be the same with or similar to each other. Therefore, deviations in the length of power lines that connect the first to eighth data output drivers DQ0_OUT to DQ7_OUT and the first power supply voltage pads in the first region R1 and the second region R2 may be eliminated or minimized.

When there are deviations in tDQSQ between read data output from a semiconductor memory device, characteristics of read data may deteriorate. One of factors that causes a tDQSQ deviation between read data may be a power distribution network (PDN) mismatch in VCCQ voltage between read data.

For example, when read data transitions occur and the pull-up transistor or the pull-down transistor of a data output driver is turned on/off, VCCQ voltage fluctuates due to instantaneous current consumption, and thus, a time point at which the read data is outputted changes. If settling times of VCCQ voltages are different from each other due to a PDN mismatch in VCCQ voltage between read data, time points at which the read data are outputted may become different, which may cause a tDQSQ deviation between the read data.

According to embodiment of the present disclosure, because deviations in the length of power lines that connect data output drivers and first power supply voltage pads may be eliminated or minimized, a PDN mismatch in VCCQ voltage between read data may be eliminated or minimized and a tDQSQ deviation between read data may be reduced, whereby read characteristics may be improved.

The first data output driver DQ0_OUT and the second data output driver DQ1_OUT may be connected to the second power supply voltage pad VCCQL1, and may be supplied with a second power supply voltage from the second power supply voltage pad VCCQL1. The third data output driver DQ2_OUT and the fourth data output driver DQ3_OUT may be connected to the second power supply voltage pad VCCQL2, and may be supplied with a second power supply voltage from the second power supply voltage pad VCCQL2.

The fifth data output driver DQ4_OUT and the sixth data output driver DQ5_OUT may be connected to the second power supply voltage pad VCCQL5, and may be supplied with a second power supply voltage from the second power supply voltage pad VCCQL5. The seventh data output driver DQ6_OUT and the eighth data output driver DQ7_OUT may be connected to the second power supply voltage pad VCCQL6, and may be supplied with a second power supply voltage from the second power supply voltage pad VCCQL6.

The first to eighth data input circuits DQ0_IN to DQ7_IN may be connected to the first to eighth data input/output pads DQ0 to DQ7, respectively. The first to eighth data input circuits DQ0_IN to DQ7_IN may receive external data from the memory controller through the first to eighth data input/output pads DQ0 to DQ7. External data may be single-ended signals.

Each of the first to eighth data input circuits DQ0_IN to DQ7_IN may be disposed in a region adjacent to a corresponding data input/output pad. Accordingly, the length of a signal line that connects a data input/output pad and a data input circuit may be configured to be as short as possible, and time delays from when data is received through the data input/output pad to transmission to the data input circuit may be reduced.

The first to eighth data input circuits DQ0_IN to DQ7_IN may be connected to the first to eighth reference voltage generation circuits DAC0 to DAC7, respectively. Each of the first to eighth data input circuits DQ0_IN to DQ7_IN may receive a reference voltage from a corresponding reference voltage generation circuit. A reference voltage may be used as a reference signal for distinguishing whether the value of external data is 0 or 1.

Each of the first to eighth reference voltage generation circuits DAC0 to DAC7 may be disposed adjacent to a corresponding data input circuit. Accordingly, a reference voltage transmission path may be configured to be as short as possible, and the settling time of a reference voltage may be shortened as a result.

Each of the first to eighth data input circuits DQ0_IN to DQ7_IN may generate internal data by comparing external data with a reference voltage. When the external data exceeds the value of the reference voltage, the value of the internal data may be determined as 1, and when the external data does not exceed the value of the reference voltage, the value of the internal data may be determined as 0.

The first to eighth data input circuits DQ0_IN to DQ7_IN may output internal data to a memory region inside the semiconductor memory device in response to a data strobe signal, and accordingly, data may be written to the memory region.

Each of the first to eighth reference voltage generation circuits DAC0 to DAC7 may generate a reference voltage according to a voltage setting code. Each of the first to eighth reference voltage generation circuits DAC0 to DAC7 may generate a reference voltage that has a voltage level corresponding to the voltage setting code. The target level of a reference voltage may be, for example, the mid level of the swing range of data transmitted through a transmission line that connects the memory controller and the semiconductor memory device. Each of the first to eighth reference voltage generation circuits DAC0 to DAC7 may change the level of a reference voltage according to the voltage setting code. The voltage setting code may be transmitted from the memory controller. The voltage setting code may be information that is stored in an information storage region such as a mode register in the semiconductor memory device. The voltage setting code may vary through a training operation between the memory controller and the semiconductor memory device. Each of the first to eighth reference voltage generation circuits DAC0 to DAC7 may be configured with a digital-to-analog converter.

The data strobe pads may include a first differential data strobe pad DQS_t and a second differential data strobe pad DQS_c. A first signal, which is received by the first differential data strobe pad DQS_t, and a second signal, which is received by the second differential data strobe pad DQS_c, may have the same amplitude and opposite phases. The data strobe signal input circuit DQS_IN may generate a data strobe signal using the first and second signals. For example, the rising edge of the data strobe signal may correspond to a time point at which the first signal and the second signal intersect with each other. Each of the first to eighth data input circuits DQ0_IN to DQ7_IN may generate internal data using the rising edge of the data strobe signal.

As described above, because the first to fourth data input/output pads DQ0 to DQ3 are disposed in the first region R1, the fifth to eighth data input/output pads DQ4 to DQ7 are disposed in the second region R2, and the data strobe pads DQS_t and DQS_c are disposed in the third region R3 between the first region R1 and the second region R2, compared to a device in which data strobe pads are disposed in a region outside the first, second and third regions R1, R2 and R3, the skews of data strobe signals between the first to fourth data input/output pads DQ0 to DQ3 included in the first region R1 and the fifth to eighth data input/output pads DQ4 to DQ7 included in the second region R2 may be shortened. Accordingly, a deviation in tDVW (data valid window) between read data may be reduced.

The read enable pads may include a first differential read enable pad RE_t and a second differential read enable pad RE_c. A first read enable signal, which is inputted through the first differential read enable pad RE_t, and a second read enable signal, which is inputted through the second differential read enable pad RE_c, may have the same amplitude and opposite phases. The first and second read enable signals may be enabled when transmitting data to a transmission line in the semiconductor memory device.

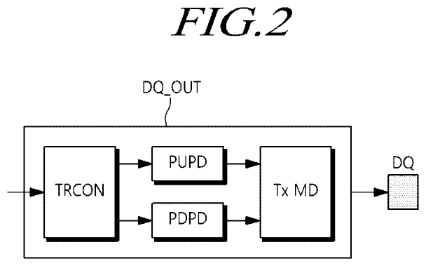

FIG. 2 is a block diagram of a data output driver according to an embodiment of the present disclosure.

Referring to FIG. 2, a data output driver DQ_OUT may include a trigger control unit TRCON, a pull-up pre-driver PUPD, a pull-down pre-driver PDPD and a main driver Tx MD.

The trigger control unit TRCON may receive read data from a memory region through column lines, and may generate a pull-up pulse and a pull-down pulse according to the received read data.

The pull-up pre-driver PUPD may generate a pull-up code including pull-up data in response to the pull-up pulse provided from the trigger control unit TRCON. The pull-down pre-driver PDPD may generate a pull-down code including pull-down data in response to the pull-down pulse provided from the trigger control unit TRCON.

The main driver Tx MD may include a pull-up main driver and a pull-down main driver. The pull-up main driver may output high output data to a data input/output pad DQ in response to the pull-up data and the pull-up code provided from the pull-up pre-driver PUPD. For example, the pull-up main driver may output high output data to the data input/output pad DQ when low pull-up data is received. The pull-up main driver might not output output data when high pull-up data is received. The pull-down main driver may output low output data to the data input/output pad DQ in response to the pull-down data and the pull-down code provided from the pull-down pre-driver PDPD. For example, the pull-down main driver may output low output data to the data input/output pad DQ when high pull-down data is received. The pull-down main driver might not output output data when low pull-down data is received.

The trigger control unit TRCON, the pull-up pre-driver PUPD and the pull-down pre-driver PDPD use a VCCQ voltage as a power supply voltage. In order to reduce power consumption, the main driver Tx MD uses a VCCQL voltage as a power supply voltage, instead of a VCCQ voltage. The VCCQ voltage is a first constant voltage, and the VCCQL voltage may be selected from a second constant voltage or a third constant voltage. The second constant voltage may have the same value as the first constant voltage, and the third constant voltage may have a smaller value than the first constant voltage. For example, the first and second constant voltages may be 1.2 V, and the third constant voltage may be 0.6 V.

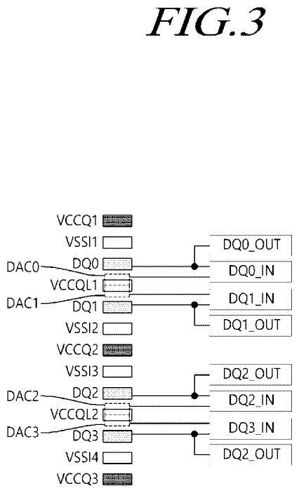

FIG. 3 is a schematic plan view of a semiconductor memory device according to an embodiment of the present disclosure.

Referring to FIG. 3, a first reference voltage generation circuit DAC0 may be connected to a first data input circuit DQ0_IN, and may provide a reference voltage to the first data input circuit DQ0_IN. A second reference voltage generation circuit DAC1 may be connected to a second data input circuit DQ1_IN, and may provide a reference voltage to the second data input circuit DQ1_IN.

When viewed in a plan view, the first and second reference voltage generation circuits DAC0 and DAC1 may be disposed between a first data input/output pad DQ0 and a second data input/output pad DQ1. In an embodiment, at least a portion of each of the first and second reference voltage generation circuits DAC0 and DAC1 may vertically overlap a second power supply voltage pad VCCQL1, which in the plan view is disposed between the first data input/output pad DQ0 and the second data input/output pad DQ1.

A third reference voltage generation circuit DAC2 may be connected to a third data input circuit DQ2_IN, and may provide a reference voltage to the third data input circuit DQ2_IN. A fourth reference voltage generation circuit DAC3 may be connected to a fourth data input circuit DQ3_IN, and may provide a reference voltage to the fourth data input circuit DQ3_IN.

When viewed in a plan view, the third and fourth reference voltage generation circuits DAC2 and DAC3 may be disposed between a third data input/output pad DQ2 and a fourth data input/output pad DQ3. In an embodiment, at least a portion of each of the third and fourth reference voltage generation circuits DAC2 and DAC3 may vertically overlap a second power supply voltage pad VCCQL2, which in the plan view is disposed between the third data input/output pad DQ2 and the fourth data input/output pad DQ3.

According to embodiments of the present disclosure, because the first and second reference voltage generation circuits DAC0 and DAC1 are disposed between the first data input/output pad DQ0 and the second data input/output pad DQ1, a length deviation between a signal line that connects the first reference voltage generation circuit DAC0 and the first data input circuit DQ0_IN and a signal line that connects the second reference voltage generation circuit DAC1 and the second data input circuit DQ1_IN may be eliminated or minimized. Because the third and fourth reference voltage generation circuits DAC2 and DAC3 are disposed between the third data input/output pad DQ2 and the fourth data input/output pad DQ3, a length deviation between a signal line that connects the third reference voltage generation circuit DAC2 and the third data input circuit DQ2_IN and a signal line that connects the fourth reference voltage generation circuit DAC3 and the fourth data input circuit DQ3_IN may be eliminated or minimized. Therefore, by reducing the settling time mismatch between reference voltages, write characteristics may be improved.

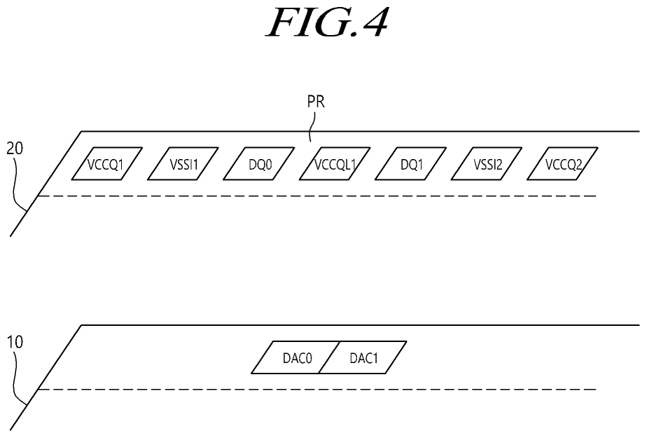

FIG. 4 is a perspective view illustrating pads and reference voltage generation circuits of a semiconductor memory device according to an embodiment of the present disclosure.

Referring to FIG. 4, a semiconductor memory device may include a substrate 10 and a pad layer 20 which is disposed on the substrate 10.

The first and second reference voltage generation circuits DAC0 and DAC1 may be configured in a substrate 10. Although not illustrated, data input circuits, data output drivers and a data strobe input circuit may be further configured in the substrate 10.

In a pad region PR of the pad layer 20, a first power supply voltage pad VCCQ1, a ground pad VSSI1, the first data input/output pad DQ0, the second power supply voltage pad VCCQL1, the second data input/output pad DQ1, a ground pad VSSI2 and a first power supply voltage pad VCCQ2 may be configured. Although not illustrated, the pads of FIG. 1 may be configured in the pad region PR.

A portion of the first reference voltage generation circuit DAC0 may vertically overlap with the second power supply voltage pad VCCQL1, which is disposed in the pad layer 20 between the first data input/output pad DQ0 and the second data input/output pad DQ1. A portion of the second reference voltage generation circuit DAC1 may vertically overlap with the second power supply voltage pad VCCQL1, which is disposed in the pad layer 20 between the first data input/output pad DQ0 and the second data input/output pad DQ1.

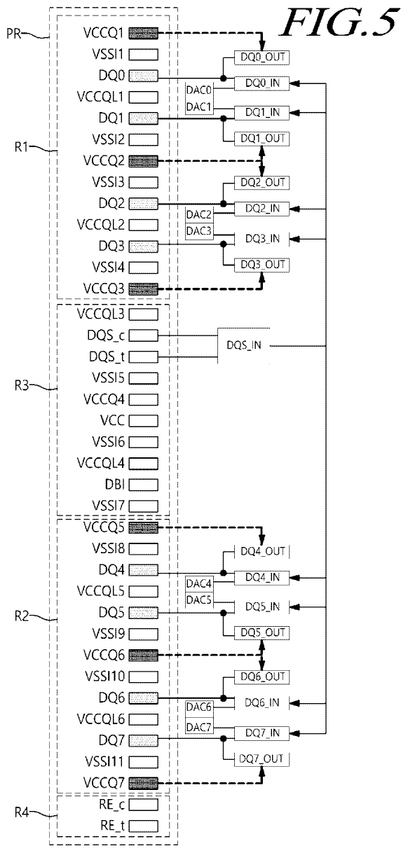

FIG. 5 is a schematic plan view of a semiconductor memory device according to an embodiment of the present disclosure.

Referring to FIG. 5, a pad region PR may include first to fourth regions R1 to R4. The first to fourth regions R1 to R4 may be disposed in a line. The third region R3 may be disposed between the first region R1 and the second region R2, and the fourth region R4 may be disposed outside the first, second and third regions R1, R2 and R3. In an embodiment, the fourth region R4 may be disposed on a side of the second region R2 opposite to the third region R3.

Read enable pads RE_t and RE_c may be disposed in the fourth region R4. Because the read enable pads RE_t and RE_c are disposed in the fourth region R4, compared to a structure where read enable pads are disposed in a third region, the skew of data strobe signal between first to fourth data input/output pads DQ0 to DQ3 included in the first region R1 and fifth to eighth data input/output pads DQ4 to DQ7 included in the second region R2 may be reduced.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor memory device comprising:
a pair of first power supply voltage pads;
a second power supply voltage pad;
a first data input/output pad connected to a first data output driver; and
a second data input/output pad connected to a second data output driver,
wherein the first data output driver is connected to one of the pair of first power supply voltage pads, and the second data output driver is connected to the other of the pair of first power supply voltage pads, and
wherein the first data input/output pad is disposed between one of the pair of first power supply voltage pads and the second power supply voltage pad, and the second data input/output pad is disposed between the other of the pair of first power supply voltage pads and the second power supply voltage pad.

2. The semiconductor memory device according to claim 1, wherein a spacing between one of the pair of first power supply voltage pads and the first data input/output pad and a spacing between the other of the pair of first power supply voltage pads and the second data input/output pad are the same.

3. The semiconductor memory device according to claim 1, further comprising:
a first ground pad disposed between one of the pair of first power supply voltage pads and the first data input/output pad; and
a second ground pad disposed between the other of the pair of first power supply voltage pads and the second data input/output pad.

4. The semiconductor memory device according to claim 1, wherein the first data output driver and the second data output driver are connected in common to the second power supply voltage pad.

5. The semiconductor memory device according to claim 1, wherein
a first constant voltage is provided to the pair of first power supply voltage pads, and
a second constant voltage or a third constant voltage is provided to the second power supply voltage pad.

6. The semiconductor memory device according to claim 5, wherein the second constant voltage is the same as the first constant voltage, and the third constant voltage is lower than the first constant voltage.

7. A semiconductor memory device comprising:
a plurality of first power supply voltage pads;
a plurality of second power supply voltage pads; and
a plurality of data input/output pads connected to a plurality of data output drivers, respectively,
wherein, from among the plurality of first power supply voltage pads and from among the plurality of second power supply voltage pads, a first power supply voltage pad is disposed between a pair of adjacent second power supply voltage pads,
wherein, from among the plurality of data input/output pads, a first data input/output pad is disposed between one of a pair of second power supply voltage pads and the first power supply voltage pad, and a second data input/output pad is disposed between the other of the pair of second power supply voltage pads and the first power supply voltage pad, and
wherein a data output driver connected to the first data input/output pad and a data output driver connected to the second data input/output pad are connected in common to the first power supply voltage pad.

8. The semiconductor memory device according to claim 7, wherein a spacing between the first data input/output pad and the first power supply voltage pad and a spacing between the second data input/output pad and the first power supply voltage pad are the same.

9. The semiconductor memory device according to claim 7, further comprising:
a first ground pad disposed between the first power supply voltage pad and the first data input/output pad; and
a second ground pad disposed between the first power supply voltage pad and the second data input/output pad.

10. The semiconductor memory device according to claim 7, further comprising:
a data strobe pad,
wherein the plurality of data input/output pads are divided into two groups to be disposed in a first region and a second region, respectively, and
wherein the data strobe pad is disposed in a third region disposed between the first region and the second region.

11. The semiconductor memory device according to claim 10, further comprising:
a read enable pad,
wherein the read enable pad is disposed in a fourth region outside the first, second and third regions.

12. A semiconductor memory device comprising:
first and second data input/output pads defined in a pad layer on a substrate;
a first data input circuit defined in the substrate and connected to the first data input/output pad;
a second data input circuit defined in the substrate and connected to the second data input/output pad;
a first reference voltage generation circuit defined in the substrate, and providing a reference voltage to the first data input circuit;
a second reference voltage generation circuit defined in the substrate, and providing a reference voltage to the second data input circuit; and
a first power supply voltage pad defined in the pad layer, and disposed between the first data input/output pad and the second data input/output pad,
wherein, when viewed in a plan view, the first and second reference voltage generation circuits are disposed between the first data input/output pad and the second data input/output pad.

13. The semiconductor memory device according to claim 12, wherein at least a portion of each of the first reference voltage generation circuit and the second reference voltage generation circuit vertically overlaps the first power supply voltage pad in the plan view.

14. The semiconductor memory device according to claim 12, further comprising:
a first data output driver defined in the substrate, and connected to the first data input/output pad;
a second data output driver defined in the substrate, and connected to the second data input/output pad; and
a pair of second power supply voltage pads defined in the pad layer,
wherein the first data output driver is connected to one of the pair of second power supply voltage pads, and the second data output driver is connected to the other of the pair of second power supply voltage pads, and
wherein the first data input/output pad is disposed between the first power supply voltage pad and one of the pair of second power supply voltage pads, and the second data input/output pad is disposed between the first power supply voltage pad and the other of the pair of second power supply voltage pads.

15. The semiconductor memory device according to claim 14, wherein a spacing between one of the pair of second power supply voltage pads and the first data input/output pad and a spacing between the other of the pair of second power supply voltage pads and the second data input/output pad are the same.

16. The semiconductor memory device according to claim 14, further comprising:
a first ground pad disposed between one of the pair of second power supply voltage pads and the first data input/output pad; and
a second ground pad disposed between the other of the pair of second power supply voltage pads and the second data input/output pad.

17. The semiconductor memory device according to claim 14, wherein the first data output driver and the second data output driver are connected in common to the first power supply voltage pad.
